(19) United States
(12) Patent Application Publication
(10) Pub. No.: US 2025/0259921 A1
(43) Pub. Date: Aug. 14, 2025

(54) PACKAGE SUBSTRATE AND SEMICONDUCTOR PACKAGE INCLUDING THE PACKAGE SUBSTRATE

(71) Applicant: Samsung Electronics Co., Ltd., Suwon-si (KR)

(72) Inventors: Seokbeom YONG, Suwon-si (KR); Juwon KIM, Suwon-si (KR); Eunkyeong PARK, Suwon-si (KR); Sangsub SONG, Suwon-si (KR); Sungoh AHN, Suwon-si (KR); Seulgi YU, Suwon-si (KR)

(73) Assignee: Samsung Electronics Co., Ltd., Suwon-si (KR)

(21) Appl. No.: 18/822,728

(22) Filed: Sep. 3, 2024

(30) Foreign Application Priority Data
Feb. 14, 2024 (KR) 10-2024-0020902

(51) Int. Cl. H01L 23/498

(52) U.S. Cl. CPC H01L 23/49827; H01L 23/49822

(57) ABSTRACT

A package substrate may include a core layer, a first line layer on a lower surface of the core layer and including multiple layers of first lines, and a second line layer on an upper surface of the core layer and including multiple layers of second lines. The core layer may include a core body and a core via. The core via may penetrate the core body and extend in a vertical direction. A first signal line of the first lines may be connected to a second signal line of the second lines through the core via. The first signal line may be arranged in a form of an inductor in the first line layer.

### CROSS-REFERENCE TO RELATED APPLICATION

This application is based on and claims priority under 35 U.S.C. § 119 to Korean Patent Application No. 10-2024-0020902, filed on Feb. 14, 2024, in the Korean Intellectual Property Office, the disclosure of which is incorporated by reference herein in its entirety.

### BACKGROUND

Inventive concepts relate to a semiconductor package, and more particularly, to a package substrate and a semiconductor package including the package substrate.

According to the rapid development of the electronics industry and user demands, electronic devices have become smaller and lighter. As electronic devices have become smaller and lighter, semiconductor packages used in electronic devices also have become smaller and lighter, and the semiconductor packages also may be required to have high reliability together with high performance and large capacity. For example, regarding the reliability of the semiconductor packages, as the semiconductor packages have become smaller and have increased in operating speeds, problems with signal integrity (SI) characteristics may occur due to noise. Accordingly, research and development on package structures capable of addressing SI characteristics problems have been continuously conducted.

### SUMMARY

Inventive concepts provide a package substrate with improved signal integrity (SI) characteristics and physical reliability of a substrate, and a semiconductor package including the package substrate.

In addition, aspects of inventive concepts are not limited to those mentioned above, and other aspects may be clearly understood by those skilled in the art from the description below.

According to an embodiment of inventive concepts, a package substrate may include a core layer; a first line layer on a lower surface of the core layer and including multiple layers of first lines; and a second line layer on an upper surface of the core layer and including multiple layers of second lines. The core layer may include a core body and a core via. The core via may penetrate the core body and may extend in a vertical direction. A first signal line of the first lines may be connected to a second signal line of the second lines through the core via, and the first signal line may be arranged in a form of an inductor in the first line layer.

According to an embodiment of inventive concepts, a package substrate may include a body layer having an upper surface and a lower surface; and multiple layers of lines in the body layer. The lines may include a signal line configured to transmit a signal. The signal line may include a horizontal line and a vertical via. The horizontal line may extend in the body layer in a horizontal direction parallel to the upper surface of the body layer. The vertical via may be configured to connect adjacent horizontal lines in a vertical direction to each other in the body layer. The vertical direction may be perpendicular to the horizontal direction, and the horizontal line and the vertical via may configure an inductor in the body layer.

According to an embodiment of inventive concepts, a semiconductor package may include a package substrate; at least one semiconductor device mounted on the package substrate; and a sealant configured to seal the at least one semiconductor device on the package substrate. The package substrate may include a body layer having an upper surface and a lower surface and multiple layers of lines in the body layer. The lines may include a signal line configured to transmit a signal. The signal line may include a horizontal line and a vertical via. The horizontal line may extend in the body layer in a horizontal direction parallel to the upper surface of the body layer, and the vertical via may be configured to connect adjacent horizontal lines in a vertical direction to each other in the body layer. The horizontal line and the vertical via may configure an inductor in the body layer.

### BRIEF DESCRIPTION OF THE DRAWINGS

Embodiments of inventive concepts will be more clearly understood from the following detailed description taken in conjunction with the accompanying drawings in which:

FIGS. 1A and 1B are cross-sectional views of a package substrate according to an embodiment;

FIGS. 2A to 2C are three-dimensional perspective views and a cross-sectional view, each illustrating a first signal line of a first line layer in the package substrate of FIG. 1B;

FIGS. 3A and 3B are conceptual diagrams showing in a plan view a structure of an inductor formed by the first signal line in the package substrate of FIG. 1B;

FIGS. 4A and 4B are conceptual diagrams showing in a plan view the position of a first vertical via of the first signal line in the package substrate of FIG. 1B;

FIGS. 5A to 5C are cross-sectional views of package substrates according to comparative examples and a cross-sectional view of the package substrate of FIG. 1B;

FIGS. 6A and 6B are cross-sectional views for describing the physical reliability of the package substrate of a comparative example and the package substrate of FIG. 1B;

FIGS. 7A and 7B are a time domain reflectometry (TDR) graph and an insertion loss graph of a package substrate of a first comparative example and the package substrate of FIG. 1B;

FIGS. 8A and 8B are photos of the eye diagrams of the package substrate of the first comparative example and the package substrate of FIG. 1B;

FIG. 9 is a cross-sectional view of a package substrate according to an embodiment;

FIGS. 10A and 10B are a TDR graph and an insertion loss graph of the package substrate of the first comparative example and the package substrate of FIG. 9;

FIGS. 11A to 12 are cross-sectional views of semiconductor packages according to embodiments;

FIGS. 13A and 13B are a perspective view and a cross-sectional view of a semiconductor device according to an embodiment; and

FIG. 14 is a cross-sectional view of a semiconductor device according to an embodiment.

### DETAILED DESCRIPTION OF THE EMBODIMENTS

The notion that elements are “substantially the same” may indicate that the element may be completely the same and may also indicate that the elements may be determined to be the same in consideration of errors or deviations occurring during a process.

Hereinafter, inventive concepts will now be described more fully with reference to the accompanying drawings, in which embodiments of inventive concepts are shown. Like reference numerals in the drawings denote like elements, and thus their description will be omitted.

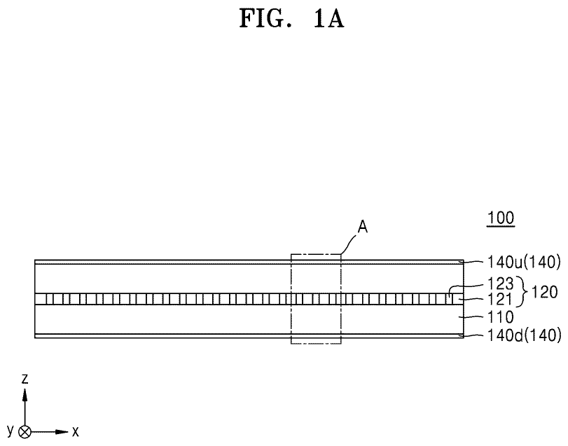

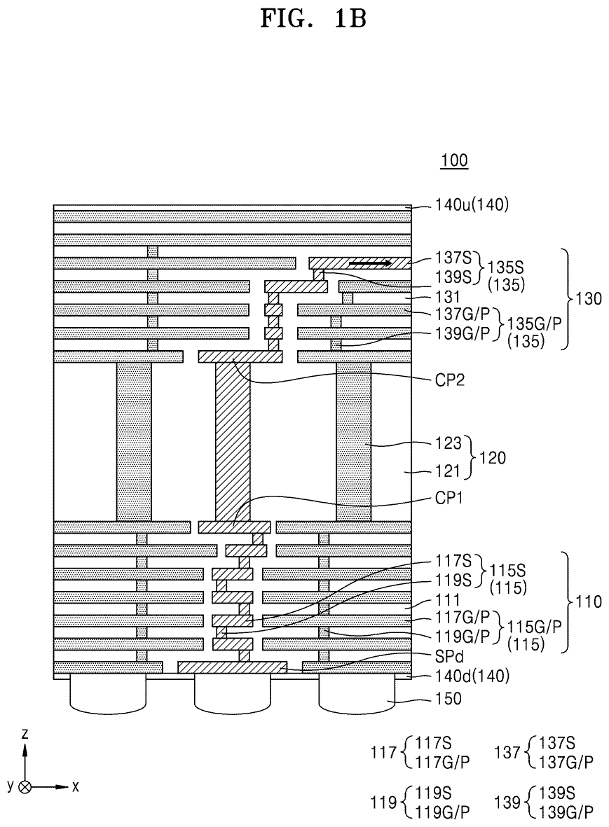

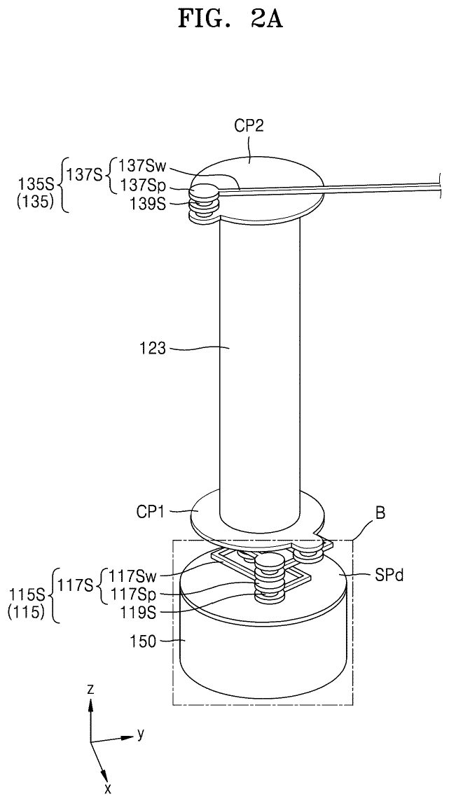

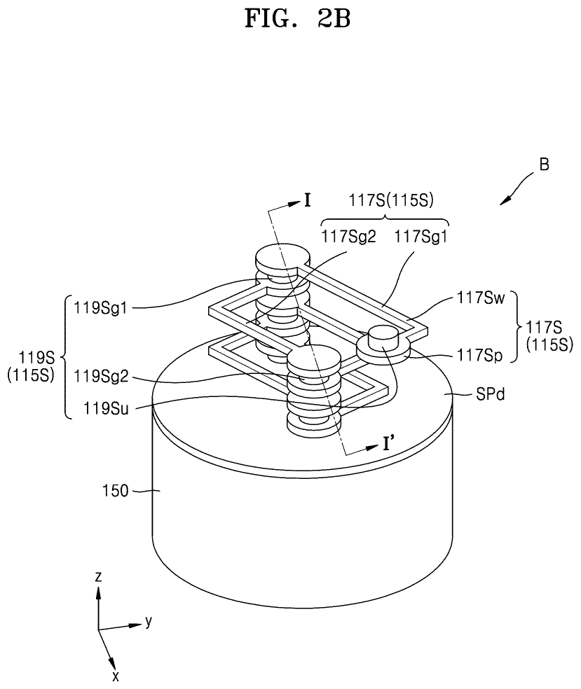

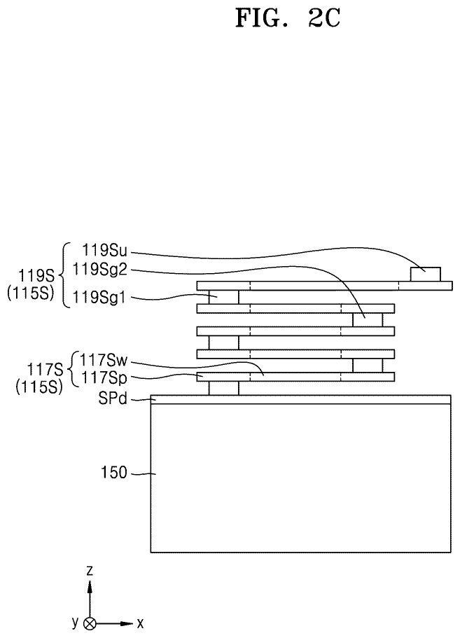

FIGS. 1A and 1B are cross-sectional views of a package substrate according to an embodiment, and FIG. 1B is an enlarged cross-sectional view of a portion A of FIG. 1A. FIGS. 2A to 2C are three-dimensional perspective views and a cross-sectional view, each illustrating a first signal line of a first line layer in the package substrate of FIG. 1B, FIG. 2B is an enlarged perspective view of a portion B of FIG. 2A, and FIG. 2C is a cross-sectional view taken along a line I-I′ of FIG. 2B.

Referring to FIGS. 1A to 2C, a package substrate 100 according to an embodiment may include a first line layer 110, a core layer 120, a second line layer 130, and a protective layer 140. The package substrate 100 may be, for example, a printed circuit board (PCB). However, the package substrate 100 is not limited to the PCB.

The core layer 120 may include a core body 121 and a core via 123. The core body 121 may include, for example, a glass fiber, such as FR4, and a resin. However, the material of the core body 121 is not limited thereto. For example, the core body 121 may include a bismaleimide-triazine (BT) resin, a polycarbonate (PC), build-up films such as an Ajinomoto build-up film, or other laminate resins. In addition, the core body 121 may also include glass, which is an inorganic material. The core body 121 may have a flat plate shape and may have a relatively thin thickness. For example, the thickness of the core body 121 may be about 40 μm to about 200 μm. However, the thickness of the core body 121 is not limited to the above range.

The core via 123 may penetrate the core body 121 and extend in a vertical direction, that is, a z direction. The core via 123 may be arranged between a first core pad CP1 and a second core pad CP2, wherein the first core pad CP1 is on the lower surface of the core via 123, and the second core pad CP2 is on the upper surface of the core via 123. For reference, the first core pad CP1 may be included as a portion of a first line 115, and the second core pad CP2 may be included as a portion of a second line 135. However, in some embodiments, the first core pad CP1 and the second core pad CP2 may also be treated as separate components from the first line 115 and the second line 135.

Each of the core via 123, the first core pad CP1, and the second core pad CP2 may include metal. For example, each of the core via 123, the first core pad CP1, and the second core pad CP2 may include copper (Cu), tungsten (W), aluminum (Al), nickel (Ni), cobalt (Co), titanium (Ti), titanium nitride (TiN), or the like. In the package substrate 100 of the embodiment, each of the core via 123, the first core pad CP1, and the second core pad CP2 may include Cu. However, the material of each of the core via 123, the first core pad CP1, and the second core pad CP2 is not limited to Cu.

The first line layer 110 may be arranged on the lower portion of the core layer 120. The first line layer 110 may include a first body 111 and the first line 115. The first body 111 may include an insulating dielectric material. For example, the first body 111 may include silicon, ceramic, an organic material, glass, an epoxy resin, or the like. In the package substrate 100 of the embodiment, the first body 111 may include, for example, prepreg (PPG). However, the material of the first body 111 is not limited to PPG. The first body 111 may have a multi-layered structure depending on the number of layers of the first line 115. For example, the first body 111 may have a structure in which a number of PPGs, which corresponds to the number of layers of the first line 115, are stacked. However, in FIG. 1B and the below cross-sectional views, for convenience of explanation, the first body 111 is shown as a single layer.

The first line 115 may be arranged within the first body 111 in multiple layers. For example, the first line 115 may be arranged within the first body 111 in three to ten layers. However, the number of layers of the first line 115 is not limited to the above range. The thickness of the first line layer 110 or the first body 111 may be different depending on the number of layers of the first line 115. In other words, the thickness of the first line layer 110 or the first body 111 may increase as the number of layers of the first line 115 increases. For example, the thickness of the first line layer 110 may be about 50 μm to about 500 μm. In a particular example, when the first line 115 is arranged within the first body 111 in four layers, the thickness of the first line layer 110 may be 250 μm. However, the thickness of the first line layer 110 and the number of layers of the first line 115 are not limited to the above ranges.

The first line 115 may include a horizontal line 117 and a vertical via 119 within the first body 111, wherein the horizontal line 117 extends in a horizontal direction, for example, an x direction and/or a y direction, and the vertical via 119 is connected to adjacent horizontal lines in the vertical direction, that is, the z direction. Each of the horizontal line 117 and the vertical via 119 may include metal. For example, each of the horizontal line 117 and the vertical via 119 may include Cu, W, Al, Ni, Co, Ti, TiN, or the like. In the package substrate 100 of the embodiment, each of the horizontal line 117 and the vertical via 119 may include, for example, Cu. However, the material of each of the horizontal line 117 and the vertical via 119 is not limited to Cu.

The first line 115 may include a lower substrate pad SPd arranged on the lowest end of the first body 111. As shown in FIG. 1B, an external connection terminal 150 may be arranged on the lower surface of the lower substrate pad SPd. In some embodiments, the lower substrate pad SPd may be treated as a different component from the first line 115. The external connection terminal 150 is a separate component from the package substrate 100, but in some embodiments, the external connection terminal 150 may also be treated as a portion of the package substrate 100.

In the package substrate 100 of the embodiment, the first line 115 may be largely divided into a first signal line 115S and a first ground/power line 115G/P. The first signal line 115S may transmit a signal, and the first ground/power line 115G/P may transmit ground or power. In more particular, the first signal line 115S may include a first horizontal line 117S of the horizontal line 117 and a first vertical via 119S of the vertical via 119. In addition, the first ground/power line 115G/P may include a first horizontal line 117G/P of the horizontal line 117 and a first vertical via 119G/P of the vertical via 119.

For reference, in terms of voice prevention, a ground line and a power line may be arranged within a package substrate in a certain area. Accordingly, the ground line may be referred to as a ground plane, and the power line may be referred to as a power plane. Therefore, in the package substrate 100 of the embodiment, the first ground/power line 115G/P may also be referred to as a first ground/power plane.

The second line layer 130 may be arranged on the upper portion of the core layer 120. The second line layer 130 may include a second body 131 and the second line 135. The second line layer 130 may be substantially the same as the first line layer 110. Accordingly, descriptions of the materials of the second body 131 and the second line 135 are omitted. The number of layers of the second line 135 may be the same as or different from the number of layers of the first line 115.

The second line 135 may include a horizontal line 137 and a vertical via 139 within the second body 131, wherein the horizontal line 137 extends in a horizontal direction, for example, the x direction and/or the y direction, and the vertical via 139 is connected to adjacent horizontal lines in the vertical direction, that is, the z direction. The materials of the horizontal line 137 and the vertical via 139 are the same as those mentioned for the horizontal line 117 and the vertical via 119. Although not illustrated in the drawings, the second line 135 may include an upper substrate pad arranged on the uppermost end of the second body 131. A connection terminal of a semiconductor chip or semiconductor package stacked on the package substrate 100 may be arranged on the upper surface of the upper substrate pad. In some embodiments, the upper substrate pad may also be treated as a different component from the second line 135.

In the package substrate 100 of the embodiment, the second line 135 may be largely divided into a second signal line 135S and a second ground/power line 135G/P. The second signal line 135S may transmit a signal, and the second ground/power line 135G/P may transmit ground or power. In more particular, the second signal line 135S may include a second horizontal line 137S of the horizontal line 137 and a second vertical via 139S of the vertical via 139. As indicated by an arrow in FIG. 1B, the second horizontal line 137S may include a relatively long portion extending in the horizontal direction. As such, the long extending portion of the second horizontal line 137S is referred to as a trace line or a routing line. The second ground/power line 135G/P may include a second horizontal line 137G/P of the horizontal line 137 and a second vertical via 139G/P of the vertical via 139. In the package substrate 100 of the embodiment, the second ground/power line 135G/P may also be referred to as a second ground/power plane.

As can be seen through FIG. 1B, the first signal line 115S may be connected to the second signal line 135S through a corresponding core via 123. In addition, the first signal line 115S may be connected to a corresponding external connection terminal 150 through the lower substrate pad SPd. The first ground/power line 115G/P may be connected to the second ground/power line 135G/P through a corresponding core via 123 and may also be connected to a corresponding external connection terminal 150 through the lower substrate pad SPd. In FIG. 1B, the first signal line 115S in the first line layer 110, the second signal line 135S in the second line layer 130, and the core via 123 of the core layer 120 corresponding to the first signal line 115S and the second signal line 135S are indicated with the same hatching. In addition, the first ground/power line 115G/P in the first line layer 110, the second ground/power line 135G/P in the second line layer 130, and the core via 123 in the core layer 120 corresponding to the first ground/power line 115G/P and the second ground/power line 135G/P are indicated with the same hatching and are distinguished from the first signal line 115S, the second signal line 135S, and the core via 123 corresponding to the first signal line 115S and the second signal line 135S.

The protective layer 140 may be a layer that protects the first line layer 110, the core layer 120, and the second line layer 130 from external physical and chemical damage. The protective layer 140 may include, for example, a solder resistor (SR). The protective layer 140 may include an upper protective layer 140u on the second line layer 130 and a lower protective layer 140d on the first line layer 110. Each of the upper protective layer 140u and the lower protective layer 140d may have a relatively thin thickness, for example, about 20 μm. However, the thickness of each of the upper protective layer 140u and the lower protective layer 140d is not limited to 20 μm.

In the package substrate 100 of the embodiment, the first signal line 115S of the first line layer 110 may form an inductor within the first body 111. In more particular, the first signal line 115S may include the first horizontal line 117S and the first vertical via 119S. In a plan view, the first vertical via 119S may be distinguished into a first vertical via group 119Sg1 arranged at a first position, a second vertical via group 119Sg2 arranged at a second position spaced apart from the first position, and an upper vertical via 119Su arranged at a third position spaced apart from the first position and the second position. In some embodiments, the upper vertical via 119Su may also be arranged at the first position or the second position to be included in the first vertical via group 119Sg1 or the second vertical via group 119Sg2.

Based on a line connecting the first vertical via group 119Sg1 and the second vertical via group 119Sg2, the first horizontal line 117S may be distinguished into a first horizontal line group 117Sg1 arranged by any one side and a second horizontal line group 117Sg2 arranged on the other side. The first horizontal line 117S may include a via pad portion 117Sp connected to the first vertical via 119S and a line portion 117Sw extending in a horizontal direction from the via pad portion 117Sp. The first horizontal line 117S and the first vertical via 119S arranged in the above structure may configure an inductor in a structure rotating clockwise or counterclockwise while the first horizontal line 117S is connected to a first horizontal line 117S of another layer through the first vertical via 119S.

In particular, in FIG. 2B, the first vertical via 119S at the lowermost end of the first vertical via group 119Sg1 may be arranged on the lower substrate pad SPd, and the first horizontal line 117S at the lowermost end of the first horizontal line group 117Sg1 may connect the first vertical via 119S at the lowermost end of the first vertical via group 119Sg1 to the first vertical via 119S at the lowermost end of the second vertical via group 119Sg2 while extending clockwise. In addition, the first horizontal line 117S at the lowermost end of the second horizontal line group 117Sg2 may connect the first vertical via 119S at the lowermost end of the second vertical via group 119Sg2 to the first vertical via 119S at the second level of the first vertical via group 119Sg1 while extending clockwise. With such a connection relationship, the first horizontal line 117S and the first vertical via 119S may extend in a z direction in the form of a spring that rotates clockwise. The first vertical via 119S at the uppermost end of the first vertical via group 119Sg1 may be connected to the first horizontal line 117S at the uppermost end of the first horizontal line group 117Sg1, and the first horizontal line 117S at the uppermost end may extend clockwise to be connected to the upper vertical via 119Su. The upper vertical via 119Su may be connected to the first core pad CP1, as shown in FIG. 2A.

In FIG. 2B, an example in which the first horizontal line 117S has a five-layered structure is shown. The number of layers of the first horizontal line 117S may be generalized to n layers and described as follows. Here, n is an integer of 3 or more. When n is an even number, the first vertical via group 119Sg1 may include a zeroth via on the lower substrate pad SPd of the package substrate 100, a second via on a second layer, . . . , and an n−2-th via on an n−2-th layer. The second vertical via group 119Sg2 may include a first via on a first layer, a third via on a third layer, . . . , and an n−1-th via on an n−1-th layer. In addition, the first horizontal line group 117Sg1 may include a first line, a third line, . . . , and an n−1-th line, and the second horizontal line group 117Sg2 may include a second line, a fourth line, . . . , and an n-th line.

When n is an odd number, the first vertical via group 119Sg1 may include a zeroth via on the lower substrate pad SPd of the package substrate 100, a second via on a second layer, . . . , and an n−1-th via on an n−1-th layer, and the second vertical via group 119Sg2 may include a first via on a first layer, a third via on a third layer, . . . , and an n−2-th via on an n−2-th layer. In addition, the first horizontal line group 117Sg1 may include a first line, a third line, . . . , an n-th line, and the second horizontal line group 117Sg2 may include a second line, a fourth line, . . . , an n−1-th line.

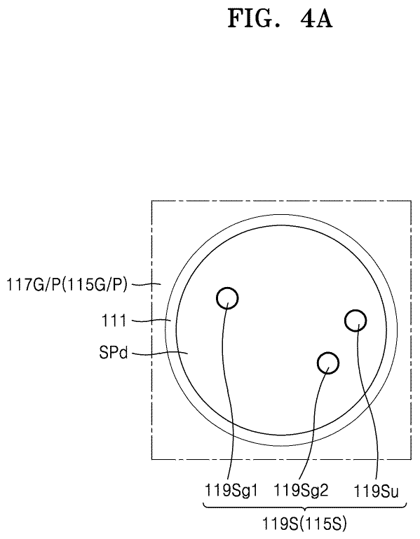

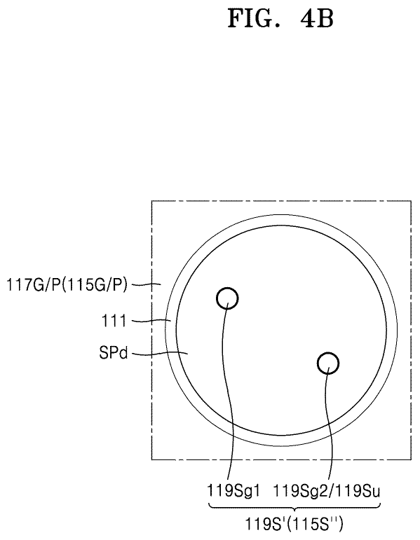

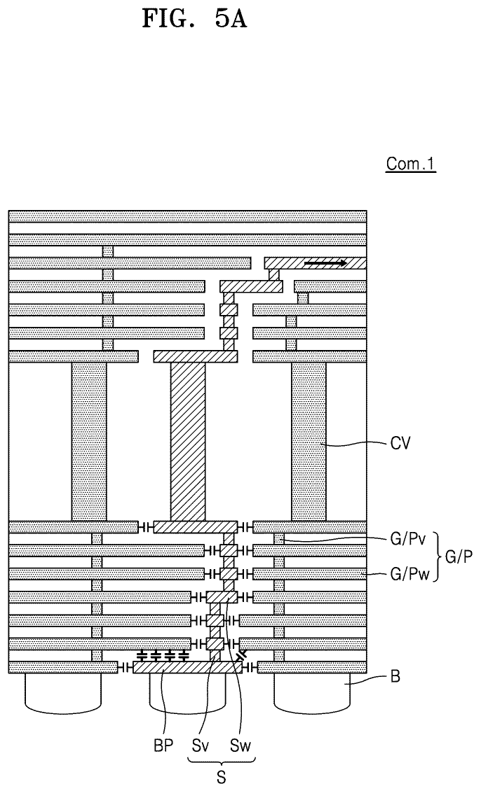

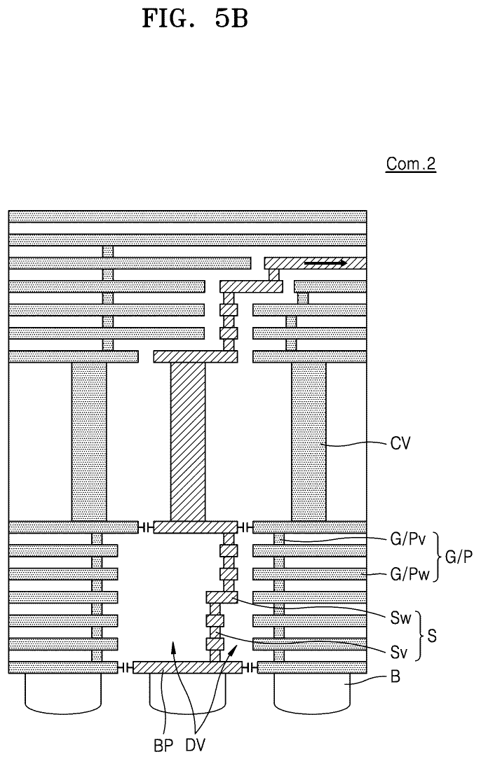

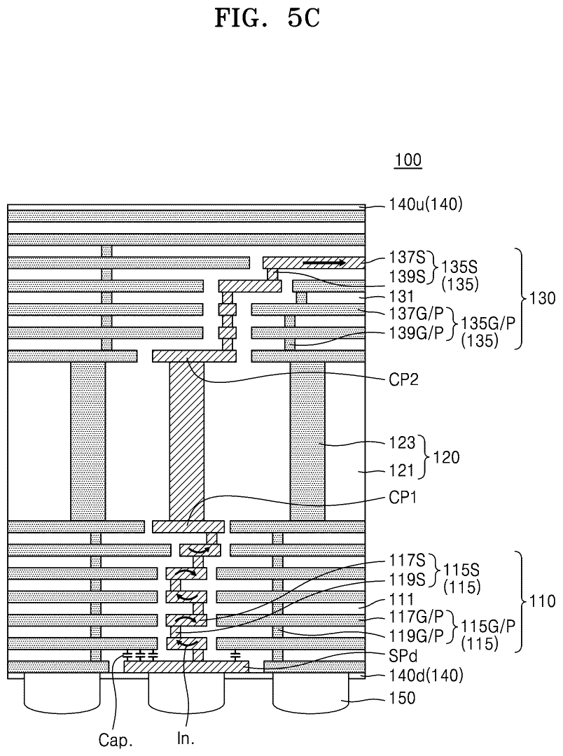

In the package substrate 100 of the embodiment, as the first signal line 115S is arranged within the first body 111 of the first line layer 110 to configure an inductor, an impedance seen at the lower substrate pad SPd may increase, and thus the variability or discontinuity of the impedance may be improved. Due to the improvement in impedance discontinuity, the insertion loss decreases, and an eye-opening value increases, and thus signal integrity (SI) characteristics of the package substrate 100 and a semiconductor package including the package substrate 100 may be improved. In addition, due to the improvement in impedance discontinuity, there is no need to generate a dielectric void (refer to DV of FIG. 5B) within the first body 111, and thus the physical reliability of the package substrate 100 may be improved. The improvement in impedance discontinuity and the improvement in physical reliability of a package substrate are described in more detail in the descriptions of FIGS. 4A to 8B.

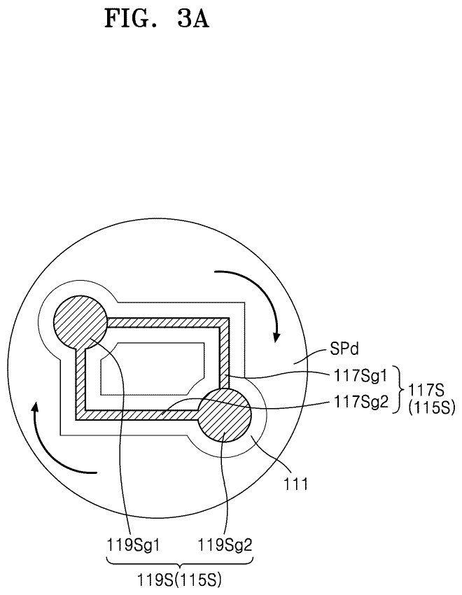

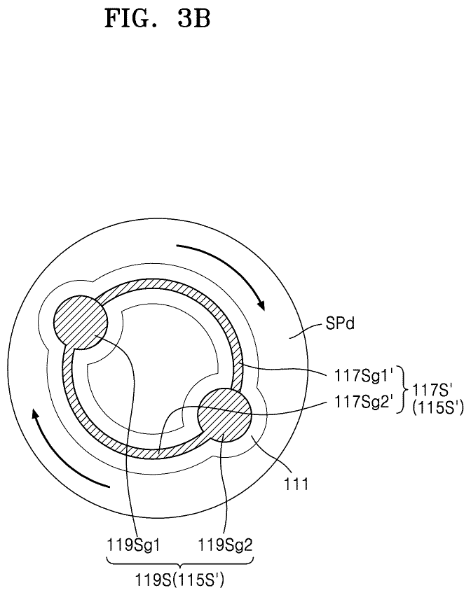

FIGS. 3A and 3B are conceptual diagrams showing the structure of an inductor formed by the first signal line in the package substrate of FIG. 1B in a plan view. Descriptions already given with reference to FIGS. 1A to 2C are simply described or omitted.

Referring to FIG. 3A, in the package substrate 100 of the embodiment, the first signal line 115S may configure an inductor within the first body 111 of the first line layer 110. In addition, the inductor configured by the first signal line 115S may have a spring form extending in a vertical direction, that is, a z direction, while rotating clockwise or counterclockwise. The inductor configured by the first signal line 115S may have a rectangular form in an x-y plane perpendicular to the z direction, as shown in FIG. 3A. For example, the first horizontal line 117S may configure four sides of a square. For reference, the arrow in FIG. 3A may mean that the inductor rotates clockwise.

Referring to FIG. 3B, in the package substrate 100 of the embodiment, an inductor configured by a first signal line 115S′ may have a spring form extending in a vertical direction, that is, a z direction, while rotating clockwise or counterclockwise. In addition, the inductor configured by the first signal line 115S′ may have a circular form in an x-y plane perpendicular to the z direction, as shown in FIG. 3B. For example, a first horizontal line 117S′ may configure the circumference of a circle. The arrow in FIG. 3B may mean that the inductor rotates clockwise.

The case where the planar form of an inductor configured by a first signal line is a square form or a circular form is described. However, the planar form of the inductor configured by the first signal line is not limited thereto. For example, the planar form of the inductor configured by the first signal line may also be an elliptical form or a polygonal form other than a square form.

FIGS. 4A and 4B are conceptual diagrams showing the position of a first vertical via of the first signal line in the package substrate of FIG. 1B in a plan view. Descriptions already given with reference to FIGS. 1A to 3B are simply described or omitted.

Referring to FIG. 4A, in the package substrate 100 of the embodiment, the first vertical via 119S of the first signal line 115S may include, on an x-y plane perpendicular to a z direction, the first vertical via group 119Sg1 arranged at a first position, the second vertical via group 119Sg2 arranged at a second position spaced apart from the first position, and the upper vertical via 119Su arranged at a third position spaced apart from the first position and the second position.

FIG. 4A shows the planar position of the first vertical via 119S as seen from the top, the large circle may correspond to the lower substrate pad SPd, and small circles may correspond to the first vertical via 119S. The outer portion of the lower substrate pad SPd may correspond to the first horizontal line 117G/P of the first ground/power line 115G/P. In addition, a space between the first horizontal line 117G/P and the lower substrate pad SPd may be filled with a dielectric material of the first body 111.

Referring to FIG. 4B, in the package substrate 100 of the embodiment, a first vertical via 119S′ of a first signal line 115S″ may include, on an x-y plane perpendicular to a z direction, the first vertical via group 119Sg1 arranged at a first position and a second vertical via group 119Sg2 arranged at a second position spaced apart from the first position. In addition, the upper vertical via 119Su may be arranged at the second position to be included in the second vertical via group 119Sg2. According to an embodiment, the upper vertical via 119Su may also be arranged at the first position to be included in the first vertical via group 119Sg1.

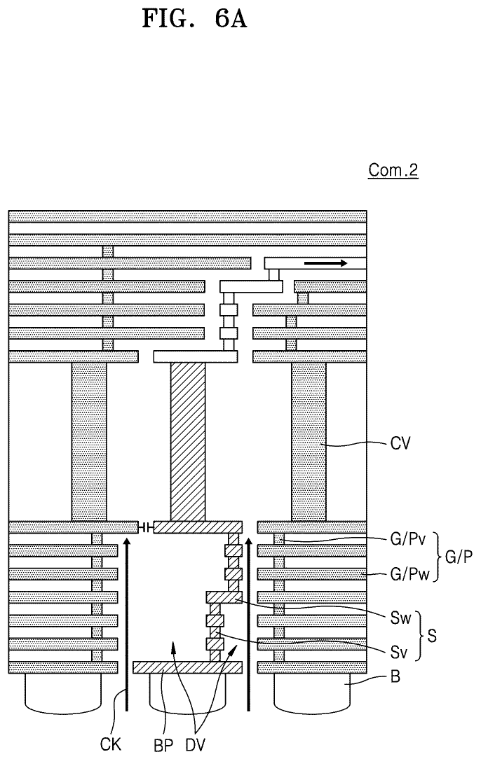

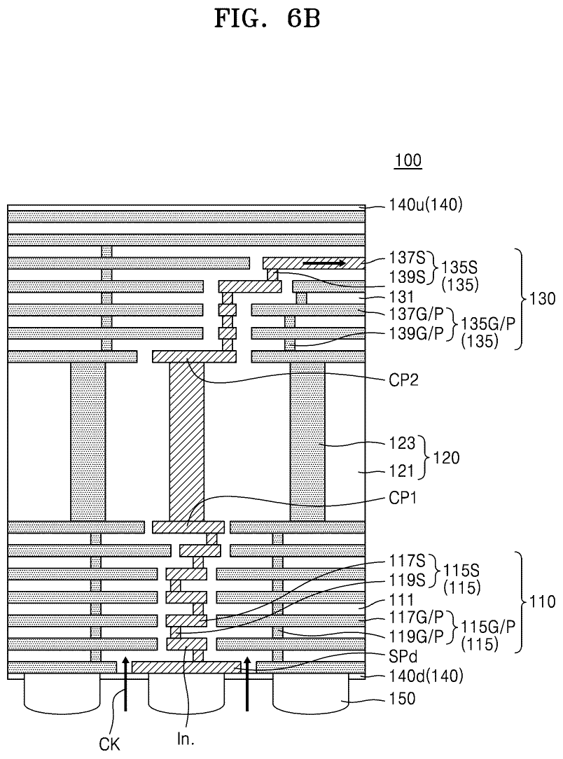

FIGS. 5A to 5C are cross-sectional views of package substrates according to comparative examples and a cross-sectional view of the package substrate of FIG. 1B, and FIGS. 6A and 6B are cross-sectional views for describing the physical reliability of the package substrate of a comparative example and the package substrate of FIG. 1B.

Referring to FIG. 5A, in the case of a package substrate Com.1 of a first comparative example, a signal line S on a ball pad BP may not include separate horizontal lines. However, as shown in FIG. 5A, the signal line S may also include about one horizontal line Sw at a mid-height position. Accordingly, the signal line S may be connected from the ball pad BP to a core via CV through vertical vias Sv without horizontal lines. For reference, a slightly wider portion between the vertical vias Sv in a z direction may correspond to a via pad.

A ground/power line G/P may be arranged adjacent to the signal line S. The ground/power line G/P may include a horizontal line G/Pw and a vertical via G/Pv. In FIG. 5A, B may mean a solder ball and may correspond to an external connection terminal of the package substrate Com. 1 of a first comparative example. In addition, the ball pad BP on which the solder ball B is arranged may correspond to a lower substrate pad of the package substrate Com.1 of a first comparative example.

Referring to FIG. 5B, in the case of a package substrate Com.2 of a second comparative example, the structure of the signal line S may be substantially the same as the structure of the signal line S of the package substrate Com.1 of the first comparative example. However, in the case of the package substrate Com.2 of the second comparative example, the ground/power line G/P on the upper portion of the ball pad BP may not be arranged directly adjacent to the signal line S, and a dielectric void DV may be formed between the signal line S and the ground/power line G/P. Here, the dielectric void DV may mean a portion filled only with a dielectric material without a conductive layer such as metal. In the package substrate Com.2 of the second comparative example, the reason that the dielectric void DV is formed between the signal line S and the ground/power line G/P on the upper portion of the ball pad BP may be to reduce the impedance variability and discontinuity.

To describe in more detail regarding impedance discontinuity, because the speed of IP (Internet Protocal)) was not fast in the related art, reducing the crosstalk/noise of a signal being ball-out, that is, a signal being output, was more important, and impedance discontinuity could be ignored to some extent. However, recently, as the speed of IP has increased, impedance discontinuity has become important. The impedance discontinuity may occur frequently in areas where ball pads, vertical vias, bump pads (or upper substrate pads), or the like are arranged, except for areas where trace lines are arranged. In particular, because a ball pad usually has a much larger area than a vertical via or a bump pad, large impedance discontinuity may occur in the area of the ball pad. The impedance discontinuity may be mainly caused by a parasitic capacitor between the signal line S and the ground/power line G/P, especially a parasitic capacitor between the ball pad BP and the ground/power line G/P, as shown in FIG. 5A. For example, in FIG. 5A, a thickly marked capacitor may have a capacitance tens to hundreds of times greater than a thinly marked capacitor.

Accordingly, to reduce impedance discontinuity, a structure in which the ground/power line G/P positioned on the upper portion of the ball pad BP is removed is used to reduce a capacitance component visible in the ball pad BP, and the package substrate Com.2 of the second comparative example of FIG. 5B may correspond to such a structure. For reference, a package substrate in a structure in which the ground/power line G/P positioned on the upper portion of the ball pad BP is removed is called a package substrate in an anti-pad structure. As can be seen through FIG. 5B, in case of a package substrate in an anti-pad structure, the dielectric void DV may be formed on the upper portion of the ball pad BP, and accordingly, the ball pad BP may not overlap the ground/power line G/P in a z direction. Such a package substrate in the anti-pad structure may be beneficial in terms of improvement on impedance discontinuity.

However, as the dielectric void DV exists on the upper portion of the ball pad BP, the package substrate may be vulnerable to physical reliability such as cracks. For example, as can be seen through FIG. 6A, when a crack CK occurs in a package substrate as indicated by the thick arrow in a z direction, the crack CK easily progresses upward through the dielectric void DV, significant physical damage may occur in the package substrate, and thus the physical reliability of the package substrate may be reduced. In addition, damage to the package substrate may lead to an open or short circuit, thereby reducing the electrical reliability of the package substrate. Furthermore, the size of a ball pad increases in a large-area package substrate, and accordingly, the size of the dielectric void DV also increases, thereby further increasing the problem of physical reliability of the package substrate.

Referring to FIG. 5C, in the case of the package substrate 100 of the embodiment, an inductor In. may be formed within the first body 111 of the first line layer 110 by the first signal line 115S. Accordingly, all of the problems of the package substrates Com.1 and Com.2 of the above comparative examples may be solved. In particular, in the case of the package substrate 100 of the embodiment, because the dielectric void DV is not formed, the problem in physical reliability of the package substrate Com.2 of the second comparative example may be solved. For example, as can be seen through FIG. 6B, even when the crack CK occurs in a package substrate as indicated by the thick arrow in a z direction, because the first ground/power line 115G/P exists on the upper portion of a lower substrate pad SPb without the dielectric void DV, the crack CK may be blocked by the first ground/power line 115G/P and may not proceed upward. That is, at least a portion of the lower substrate pad SPb may overlap the first ground/power line 115G/P in the z direction. Accordingly, physical damage to the package substrate 100 may be reduced, and the physical reliability of the package substrate 100 may be improved.

In addition, as the inductance In. by an inductor of the first signal line 115S is added, an impedance seen at a ball pad, that is, the lower substrate pad SPb, may increase, thereby improving impedance discontinuity. Accordingly, the problem in impedance discontinuity of the package substrate Com.1 of the first comparative example may be solved.

For reference, in general, a total impedance Z may be inversely proportional to the square root of a capacitance C and proportional to the square root of an inductance L, as shown in Equation (1) below.

Z∝(L/C)^{1/2} Equation (1)

Accordingly, when a capacitance increases due to a parasitic capacitor Cap., the total impedance Z decreases. To reduce such a decrease of total impedance Z, in the package substrate Com.1 of the first comparative example, a parasitic capacitor is removed by generating the dielectric void DV, and the total impedance Z is increased to improve impedance discontinuity. Conversely, in the package substrate 100 of the embodiment, as an inductor In. is added through the first signal line 115S, the total impedance Z is increased to improve impedance discontinuity.

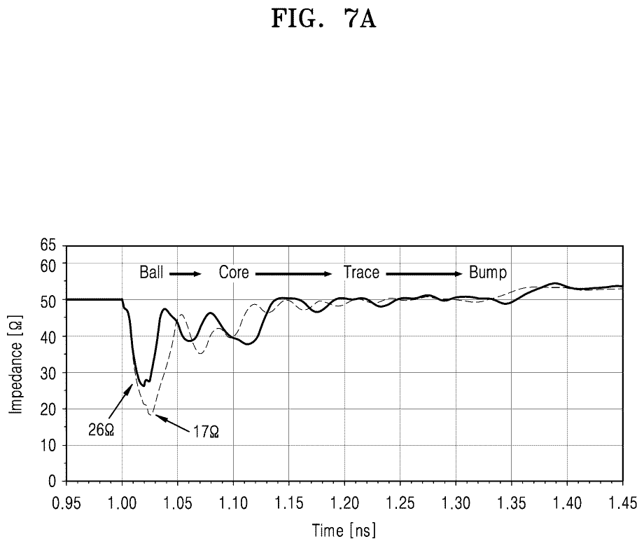

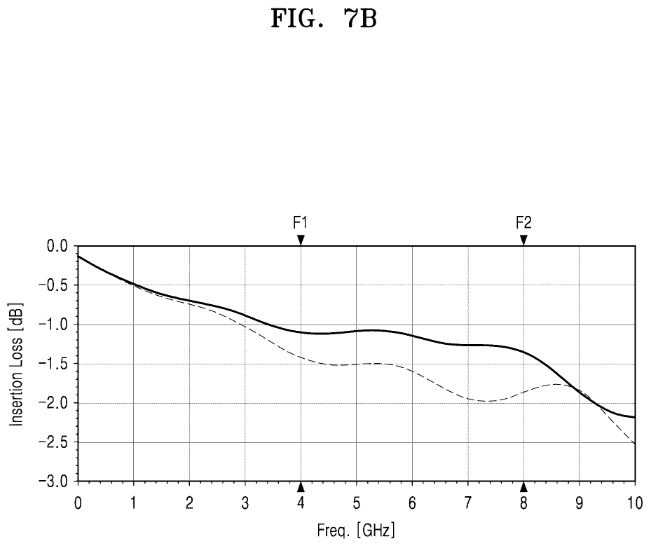

FIGS. 7A and 7B are a time domain reflectometry (TDR) graph and an insertion loss graph of a package substrate of a first comparative example and the package substrate of FIG. 1B, wherein the dotted line represents the package substrate Com. 1 of the first comparative example, and the solid line represents the package substrate 100 of FIG. 1B. In FIG. 7A, the x axis represents time and the unit thereof is nano-seconds (ns), and the y axis represents impedance and the unit thereof is ohm (22). In FIG. 7B, the x axis represents frequency and the unit thereof is gigahertz (GHz), and the y axis represents insertion loss and the unit thereof is dB.

Referring to FIG. 7A, Ball, Core, Trace, and Bump shown in the upper portion of the graph may respectively indicate the lower substrate pad SPb, the core via 123, the trace line of the second line 135, and a bump pad (or an upper substrate pad). The graph of FIG. 7A shows the impedance over time or the impedance at a corresponding position when a signal is transmitted from the external connection terminal 150.

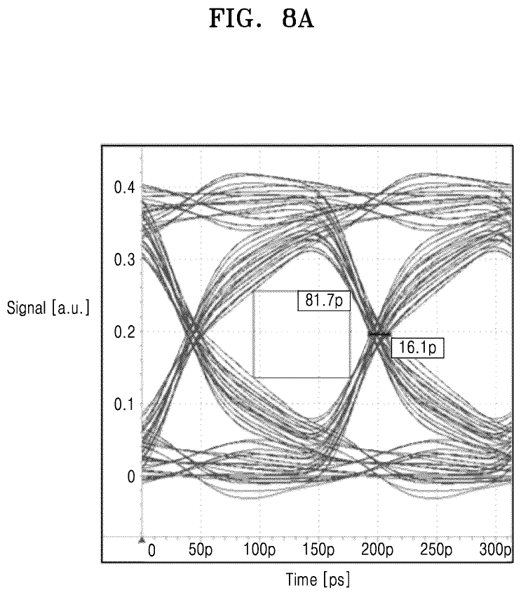

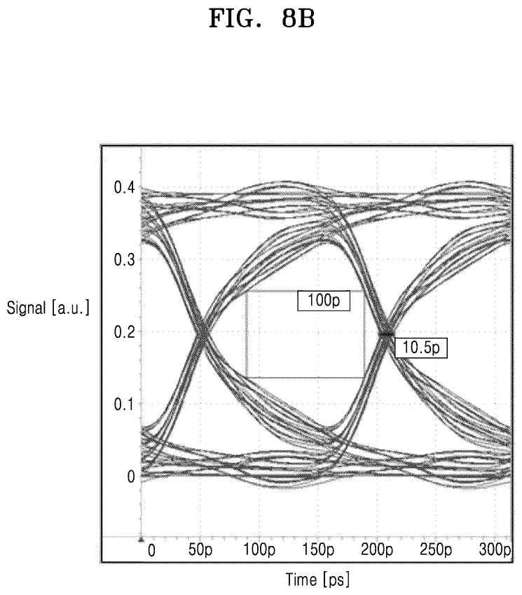

As can be seen through the graph of FIG. 7A, the impedance is significantly lowered in the portion of the lower substrate pad SPb. Such a phenomenon in which impedance varies depending on a corresponding position of a package substrate is called impedance variability or discontinuity. In addition, in the case of the package substrate Com.1 of the first comparative example, the impedance at the lower substrate pad SPb drops to 17Ω, which is less than 20Ω, and in the case of the package substrate 100 of the embodiment, the impedance at the lower substrate pad SPb is lowered to only about 26Ω, thereby improving impedance discontinuity. Such an improvement in impedance discontinuity may improve signal integrity (SI) characteristics, as can be seen in FIGS. 8A and 8B.

Referring to FIG. 7B, in the case of insertion loss, it may be confirmed that the package substrate 100 of the embodiment is improved over the package substrate Com.1 of the first comparative example. In particular, in a first frequency (4 GHZ), the insertion loss of the package substrate Com.1 of the first comparative example is −1.425 dB, and the insertion loss of the package substrate 100 of the embodiment is −1.103 dB, which can be confirmed that the insertion loss of the package substrate 100 of the embodiment has improved by about 22%. In addition, in a second frequency (8 GHZ), the insertion loss of the package substrate Com.1 of the first comparative example is −1.864 dB, and the insertion loss of the package substrate 100 of the embodiment is −1.356 dB, which can be confirmed that the insertion loss of the package substrate 100 of the embodiment has improved by about 27%.

FIGS. 8A and 8B are photos of the eye diagrams of the package substrate of the first comparative example and the package substrate of FIG. 1B. In FIGS. 8A and 8B, the x axis represents time and the unit thereof is picosecond (ps), and the y axis represents a signal voltage and the unit thereof is arbitrary.

Referring to FIGS. 8A and 8B, in the eye diagrams, the width of a portion indicated as a rectangle represents an eye-opening, and the width of an intersection portion represents an eye jitter or a timing jitter. As can be seen through FIGS. 8A and 8B, the eye-opening of the package substrate 100 of the embodiment is larger and the eye jitter thereof is smaller compared to the package substrate Com.1 of the first comparative example. In particular, when calculating with a 6.4 Gbps signal, a signal period may be 156.25 ps, the eye-opening value of the package substrate 100 of the embodiment may be calculated to be about 100/156.25=64%, and the eye-opening value of the package substrate Com.1 of the first comparative example may be calculated to be about 81.7/156.25=52%. Accordingly, it may be confirmed that the eye-opening characteristics of the package substrate 100 of the embodiment have improved by about 12% compared to the package substrate Com.1 of the first comparative example.

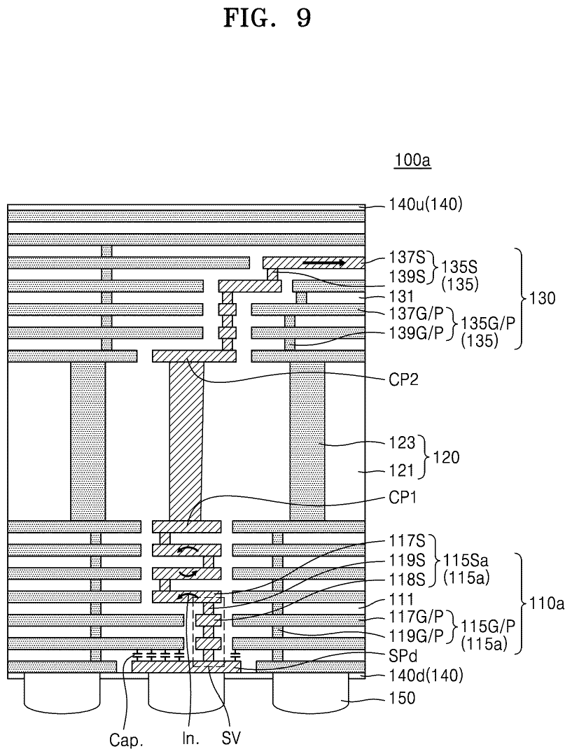

FIG. 9 is a cross-sectional view of a package substrate according to an embodiment. Descriptions already given with reference to FIGS. 1A to 6B are briefly made or omitted.

Referring to FIG. 9, a package substrate 100a according to an embodiment may be different from the package substrate 100 of FIG. 1B in the structure of a first line layer 110a. In particular, the package substrate 100a of the embodiment may include the first line layer 110a, a core layer 120, a second line layer 130, and a protective layer 140. The package substrate 100a may be, for example, a PCB. However, the package substrate 100a is not limited to a PCB. The core layer 120, the second line layer 130, and the protective layer 140 are as described in the description of the package substrate 100 of FIG. 1B.

The first line layer 110a may be arranged on the lower portion of the core layer 120. The first line layer 110a may include a first body 111 and a first line 115a. The first body 111 is as described in the description of the package substrate 100 of FIG. 1B.

The first line 115a may be arranged within the first body 111 in multiple layers. For example, the first line 115a may be arranged within the first body 111 in three layers to ten layers. However, the number of layers of the first line 115a is not limited to the above range. In the package substrate 100a of the embodiment, the first line 115a may be divided into a first signal line 115Sa and a first ground/power line 115G/P.

The first signal line 115Sa may include a stacked via SV. Here, the stacked via SV may refer to a structure in which vertical vias are stacked in the vertical direction with via pads therebetween. For example, the stacked via SV may include a first vertical via 119S and a first via pad 118S. The via pad 118S may be included in the first signal line 115Sa. In addition, as shown in FIG. 9, a first horizontal line 117S and the first vertical via 119S, which configure an inductor In., may be arranged on the upper portion of the stacked via SV.

In the package substrate 110a of the embodiment, first horizontal lines 117G/P of the first ground/power line 115G/P may surround the via pads 118S in correspondence to the stacked via SV. For example, the stacked via SV may include first via pads 118S of the first and second layers on the upper portion of a lower substrate pad SPd, and the first horizontal lines 117G/P may adjacently surround the first via pads 118S of the first and second layers. The structures of the inductor In. on the upper portion of the stacked via SV and the first horizontal lines 117G/P surrounding the inductor In. may be substantially the same as the structures of the inductor In. and the first horizontal lines 117G/P surrounding the inductor In. of the package substrate 100 of FIG. 1B.

In the package substrate 100a of the embodiment, due to the structures of the stacked via SV of the first signal line 115Sa and the ground/power line 115G/P corresponding to the stacked via SV, a crack prevention function may be strengthened by the first horizontal lines 117G/P surrounding the first via pads 118S, as described above with reference to FIG. 6B. In addition, because the inductor In. is maintained on the upper portion of the stacked via SV, the impedance may increase and impedance discontinuity may be improved.

The structures of the stacked via SV of the first signal line 115Sa and the ground/power line 115G/P are not limited to the structures of the two via pads 118S and the first horizontal lines 117G/P surrounding the via pads 118S. For example, the structures of the stacked via SV of the first signal line 115Sa and the ground/power line 115G/P may also have the structures of one or three or more layers of via pads 118S and the first horizontal lines 117G/P surrounding the via pads 118S.

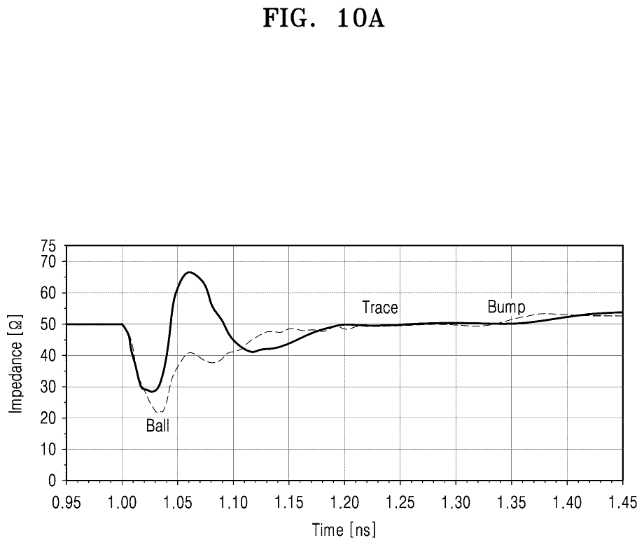

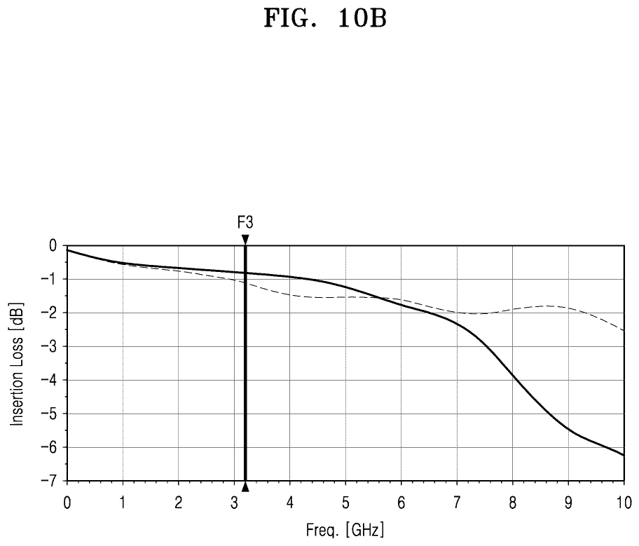

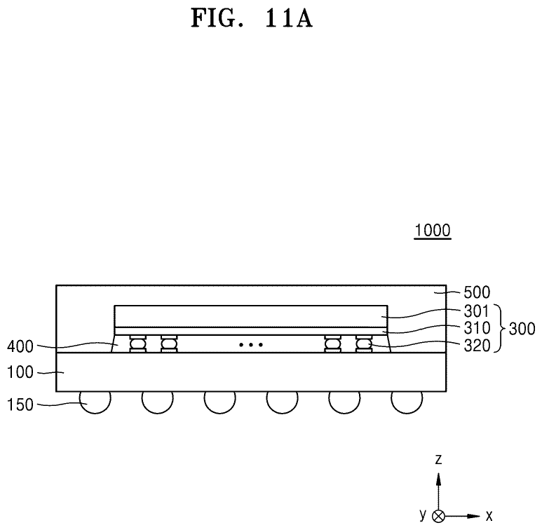

FIGS. 10A and 10B are a TDR graph and an insertion loss graph of a package substrate of a first comparative example and the package substrate of FIG. 9, wherein the dotted line represents the package substrate Com.1 of the first comparative example, and the solid line represents the package substrate 100a of FIG. 9. In FIG. 10A, the x axis represents time and the unit thereof is nano-seconds (ns), and the y axis represents impedance and the unit thereof is ohm (Ω). In FIG. 10B, the x axis represents frequency and the unit thereof is gigahertz (GHz), and the y axis represents insertion loss and the unit thereof is dB.

Referring to FIG. 10A, Ball, Trace, and Bump displayed at the top of the graph may respectively represent the lower substrate pad SPb, a trace line of the second line 135, and a bump pad (or upper substrate pad). As can be seen from the graph of FIG. 10A, it may be seen that the impedance is greatly reduced in the portion of the lower substrate pad SPb. In particular, in the case of the package substrate Com.1 of the first comparative example, the impedance drops to around 20Ω at the lower substrate pad SPb, but in the case of the package substrate 100a of the embodiment, the impedance drops only to 30Ω at the lower substrate pad SPb, and the impedance greatly increases to 65Ω immediately after the lower substrate pad SPb. Because the approximate average of an undershoot and an overshoot is about 50Ω, which becomes almost the same as the impedance of the trace line portion, and thus it may be seen that impedance discontinuity is greatly improved.

Referring to FIG. 10B, it may be seen that the insertion loss of the package substrate 100a of the embodiment is improved compared to the package substrate Com. 1 of the first comparative example due to the improvement in impedance discontinuity. In particular, at a third frequency (3.2 GHZ), the insertion loss of the package substrate Com.1 of the first comparative example is-1.111 dB, and the insertion loss of the package substrate 100a of the embodiment is −0.813 dB, which may be confirmed that the insertion loss of the package substrate 100a of the embodiment has improved by about 27%.

In addition, in the case of eye-opening characteristics, at a 6.4 Gbps signal, an eye-opening value of the package substrate Com.1 of the first comparative example may be calculated to be about 49%, and an eye-opening value of the package substrate 100a of the embodiment may be calculated to about 62%.

Accordingly, it may be confirmed that the eye-opening characteristics of the package substrate 100a of the embodiment are improved by about 13% compared to the package substrate Com.1 of the first comparative example.

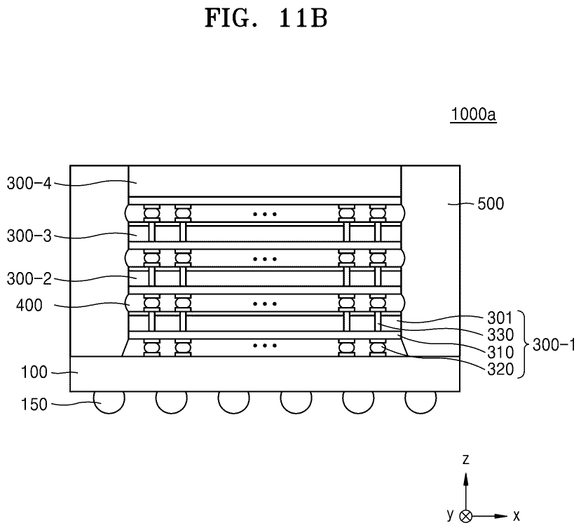

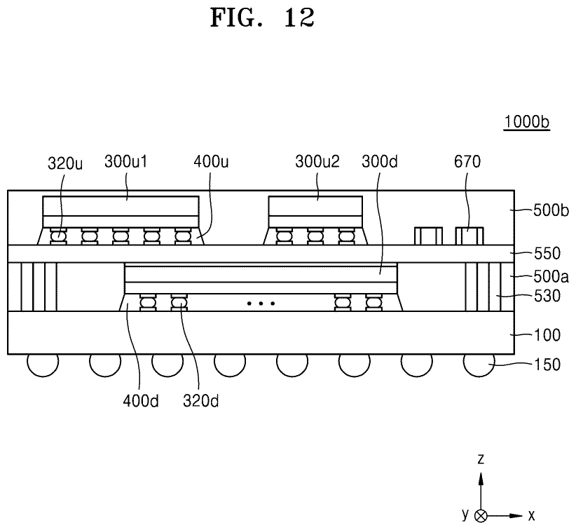

FIGS. 11A to 12 are cross-sectional views of semiconductor packages according to embodiments. Description is made with reference to FIGS. 1A and 1B together, and descriptions already given with reference to FIGS. 1A to 10B are briefly given or omitted.

Referring to FIG. 11A, a semiconductor package 1000 of an embodiment may include the package substrate 100, the external connection terminal 150, a semiconductor chip 300, an adhesive layer 400, and a sealant 500.

The package substrate 100 may be the package substrate 100 of FIG. 1A or the package substrate 100a of FIG. 9. The package substrate 100 is as described in the description with reference to FIGS. 1A to 2C. In the semiconductor package 1000 of the embodiment, the package substrate 100 may include the first signal lines 115S, 115S′, and 115S″ in various forms, as shown in FIGS. 3A to 4B. The first signal lines 115S, 115S′, and 115S″ may be arranged in the form of an inductor within the first body 111 of the first line layer 110. In FIG. 11A, the package substrate 100 is simply shown in the form of a flat plate, and particular components are omitted. Hereinafter, in the semiconductor packages 1000a, 1000b, 1000d and semiconductor devices 10000 and 10000a of other embodiments, the package substrate 100 is also shown in the form of a flat plate.

The external connection terminal 150 may be arranged on the lower surface of the package substrate 100. The external connection terminal 150 may be electrically connected to the first line 115 of the first line layer 110 through the lower substrate pad Spb. The external connection terminal 150 may be formed as a solder ball. However, according to embodiments, the external connection terminal 150 may also have a structure including a pillar and a solder. The semiconductor package 1000 of the embodiment may be mounted on a main board, a mother board, a system board, or the like of an external device through the external connection terminal 150.

The semiconductor chip 300 may be stacked on the package substrate 100. In the semiconductor package 1000 of the embodiment, although one semiconductor chip 300 is stacked on the package substrate 100, the number of semiconductor chips 300 stacked on the package substrate 100 is not limited to one. For example, a plurality of semiconductor chips 300 may be stacked on the package substrate 100. A structure in which a plurality of semiconductor chips 300 are stacked on the package substrate 100 is described in more detail with reference to FIG. 11B.

The semiconductor chip 300 may include a chip substrate 301, an element layer 310, and a bump 320. The chip substrate 301 may be based on a semiconductor material such as a silicon wafer or the like. The element layer 310 may be arranged on the lower surface of the chip substrate 301 and include various types of elements. For example, the element layer 310 may include various active and/or passive elements, for example, field effect transistors (FET) such as planar FETs or FinFETs, memory elements such as flash memory, dynamic random-access memory (DRAM), static random-access memory (SRAM), electrically erasable programmable read-only memory (EEPROM), phase-change random-access memory (PRAM), magnetoresistive random access memory (MRAM), ferroelectric random-access memory (FeRAM), resistive random-access memory (RRAM), or the like, logic elements such as AND, OR, NOT, or the like, system large scale integration (LSI), complementary metal-oxide semiconductor (CMOS) imaging sensors (CIS), and micro-electro-mechanical systems (MEMS). For example, in the semiconductor package 1000 of the embodiment, the semiconductor chip 300 may be a DRAM chip including DRAM elements in the element layer 310. Accordingly, the semiconductor package 1000 of the embodiment may be used in a high bandwidth memory (HBM) product, an electro-date processing (EDP) product, or the like. In the semiconductor package 1000 of the embodiment, the type of the semiconductor chip 300 is not limited to a DRAM chip.

The bump 320 may be arranged on the lower surface of the element layer 310 and may be electrically connected to the element layer 310 through a line. The bump 320 may include, for example, a pillar and a solder. According to embodiments, the bump 320 may also include only a solder without including a pillar.

According to embodiments, the semiconductor chip 300 may be mounted on the package substrate 100 through wire bonding. In this case, the bump 320 may be omitted. In addition, the semiconductor chip 300 may be mounted on the package substrate 100 in a structure in which the element layer 310 faces upward, and the semiconductor chip 300 may be electrically connected to the package substrate 100 through a wire.

The semiconductor chip 300 may be mounted on the package substrate 100 through the bump 320 and the adhesive layer 400. The adhesive layer 400 may be formed of an underfill or an adhesive film such as a non-conductive film (NCF). According to embodiments, the semiconductor package 1000 may be manufactured through a molded underfill (MUF) process, and in this case, the adhesive layer 400 may be omitted.

The sealant 500 may cover a portion of the upper surface of the package substrate 100, the upper surface of the semiconductor chip 300, the side surface of the semiconductor chip 300, and the side surface of the adhesive layer 400. As shown in FIG. 11A, the sealant 500 may have a certain thickness and cover the upper surface of the semiconductor chip 300. However, according to embodiments, the sealant 500 may also not cover the upper surface of the semiconductor chip 300 so that the upper surface of the semiconductor chip 300 is exposed to the outside from the sealant 500. The sealant 500 may include, for example, an epoxy mold compound (EMC). However, the material of the sealant 500 is not limited to an EMC.

Referring to FIG. 11B, the semiconductor package 1000a of the embodiment may be different from the semiconductor package 1000 of FIG. 11A in that four semiconductor chips (that is, first to fourth semiconductor chips 300-1, 300-2, 300-3, and 300-4) are stacked on the package substrate 100. In the semiconductor package 1000a of the embodiment, although four semiconductor chips (that is, first to fourth semiconductor chips 300-1, 300-2, 300-3, and 300-4) are stacked on the package substrate 100, the number of semiconductor chips stacked on the package substrate 100 is not limited to four. For example, two, three, or five or more semiconductor chips may also be stacked on the package substrate 100.

Each of the first to fourth semiconductor chips 300-1 to 300-4 is, for example, a memory chip, and may be similar to the semiconductor chip 300 of the semiconductor package 1000 of FIG. 11A. However, as shown in FIG. 11B, each of the first to third semiconductor chips 300-1 to 300-3 may further include a through silicon via (TSV) 330 penetrating the chip substrate 301. The fourth semiconductor 300-4 at the uppermost end may not include the TSV 330. The first to fourth semiconductor chips 300-1 to 300-4 may be electrically connected to the package substrate 100 through the TSVs 330 and the bump 320.

The first semiconductor chip 300-1 may be stacked on the package substrate 100 through the bump 320 and the adhesive layer 400. In addition, each of the second to fourth semiconductor chips 300-2 to 300-4 may be stacked on a corresponding lower semiconductor chip through the bump 320 and the adhesive layer 400. The adhesive layer 400 may have a structure that slightly protrudes outward from a corresponding semiconductor chip.

According to embodiments, the first to fourth semiconductor chips 300-1 to 300-4 may be mounted on the package substrate 100 through wire bonding. In this case, the first to third semiconductor chips 300-1 to 300-3 may not include TSVs 330. In addition, the first to fourth semiconductor chips 300-1 to 300-4 may be stacked on the package substrate 100 or a corresponding lower semiconductor chip through adhesive layers so that the element layer 310 faces upward. In addition, for wire bonding, the first to fourth semiconductor chips 300-1 to 300-4 may be stacked on the package substrate 100 in a zigzag structure or a staircase structure, and may be electrically connected to the package substrate 100 through wires.

The sealant 500 may cover a portion of the upper surface of the package substrate 100, the side surfaces of the first to fourth semiconductor chips 300-1 to 300-4, and the side surface of the adhesive layer 400. As shown in FIG. 11B, the upper surface of the fourth semiconductor chip 300-4 at the uppermost end may not be covered by the sealant 500. However, according to embodiments, the upper surface of the fourth semiconductor chip 300-4 may also be covered by the sealant 500.

Referring to FIG. 12, the semiconductor package 1000b of an embodiment may include the package substrate 100, the external connection terminal 150, a lower semiconductor chip 300d, upper semiconductor chips 300u1 and 300u2, first and second sealants 500a and 500b, a through post 530, a redistribution substrate 550, and a passive element 670 (e.g., resistor, capacitor, inductor). The package substrate 100 may be the package substrate 100 of FIG. 1A or the package substrate 100a of FIG. 9. The external connection terminal 150 may be arranged on the lower surface of the package substrate 100.

For reference, a structure in which external connection terminals are widely arranged beyond the lower surface of a corresponding semiconductor chip is referred to as a fan-out (FO) structure. In addition, a semiconductor package including a package substrate in an FO structure based on a wafer is referred to as an FO wafer level package (FOWLP), and a semiconductor package including a package substrate in an FO structure based on a panel is referred to as an FO panel level package (FOPLP). In the semiconductor package 1000b of the embodiment, the package substrate 100 may be based on a panel. Accordingly, the semiconductor package 1000b of the embodiment may correspond to an FOPLP.

The lower semiconductor chip 300d may be mounted on the package substrate 100 through a bump 320d and an adhesive layer 400d and may be sealed by the first sealant 500a. The lower semiconductor chip 300d may include a logic semiconductor chip and/or a memory semiconductor chip. For example, the logic semiconductor chip may be an application processor (AP), a micro-processor, a central processing unit (CPU), a controller, an application specific integrated circuit (ASIC), or the like. In addition, the memory semiconductor chip may be, for example, voltage memory such as DRAM, SRAM, or the like, or non-volatile memory such as flash memory or the like.

The through post 530 may be arranged within the first sealant 500a. The through post 530 may be formed by forming the first sealant 500a, then forming a through hole penetrating the first sealant 500a, and then filling the through hole with a conductive material. However, in another embodiment, the through post 530 may also be first formed through plating or the like, and then the first sealant 500a may also be formed to surround the through post 530.

The redistribution substrate 550 may be arranged on the lower semiconductor chip 300d and the first sealant 500a. The redistribution substrate 550 may include a redistribution line therein. The redistribution line of the redistribution substrate 550 may be connected to the through post 530 therebelow.

The upper semiconductor chips 300u1 and 300u2 and the passive element 670 may be mounted on the redistribution substrate 550 and sealed by the second sealant 500b. The upper semiconductor chips 300u1 and 300u2 may include a first upper semiconductor chip 300u1 and a second upper semiconductor chip 300u2. For example, the first upper semiconductor chip 300u1 and the second upper semiconductor chip 300u2 may be different types of memory chips. The upper semiconductor chips 300u1 and 300u2 may be stacked on the redistribution substrate 550 through a bump 320u and an adhesive layer 400u. The upper semiconductor chips 300u1 and 300u2 and the passive element 670 may be electrically connected to the redistribution line of the redistribution substrate 550.

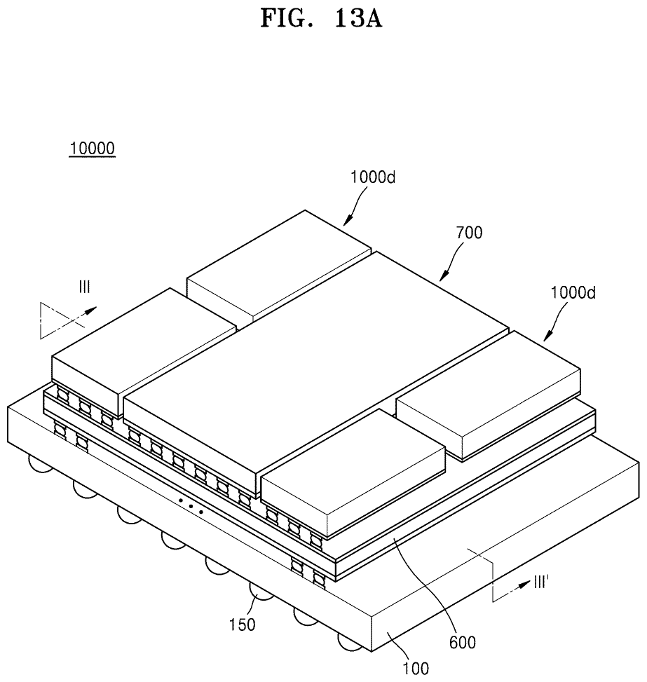

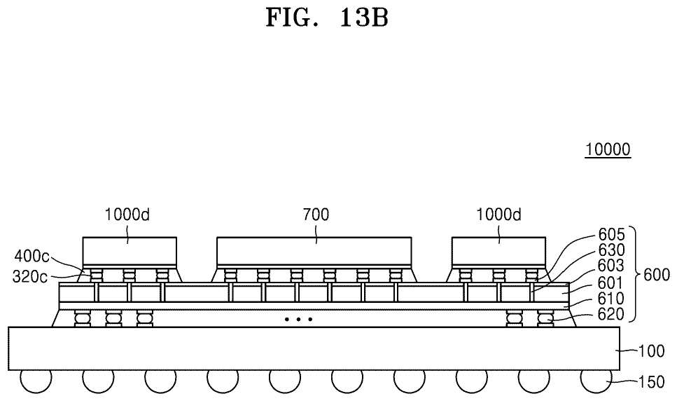

FIGS. 13A and 13B are a perspective view and a cross-sectional view of a semiconductor device according to an embodiment. Description is made with reference to FIGS. 1A and 1B together, and descriptions already given with reference to FIGS. 1A to 12 are briefly given or omitted.

Referring to FIGS. 13A and 13B, a semiconductor device 10000 of an embodiment may include the package substrate 100, the external connection terminal 150, a semiconductor package 1000d, an interposer 600, and a logic chip 700. The package substrate 100 may be the package substrate 100 of FIG. 1A or the package substrate 100a of FIG. 9. The external connection terminal 150 may be arranged on the lower surface of the package substrate 100.

The semiconductor package 1000d may be the semiconductor package 1000a of FIG. 11B. However, in the semiconductor device 10000 of the embodiment, the semiconductor package 1000d is not limited to the semiconductor package 1000a of FIG. 11B. For example, the semiconductor package 1000d may also be the semiconductor package 1000 of FIG. 11A or the semiconductor package 1000b of FIG. 12. In addition, the semiconductor package 1000d may be an HBM package. When the semiconductor package 1000d is an HBM package, the structure is similar to the semiconductor package 1000a of FIG. 11B, but a buffer chip may be placed at the bottom instead of a package substrate. In the semiconductor device 10000 of the embodiment, four semiconductor packages 1000d are mounted on the interposer 600, but the number of semiconductor packages 1000d is not limited to four. For example, one to three or five or more semiconductor packages 1000d may be mounted on the interposer 600.

The interposer 600 may include an interposer substrate 601, an upper protective layer 603, an upper pad 605, a line layer 610, a bump 620, and a through electrode 630. The semiconductor package 1000d and the logic chip 700 may be mounted on the package substrate 100 by using the interposer 600 as a medium. The interposer 600 may connect the semiconductor package 1000d and the logic chip 700 to each other, and may also connect the semiconductor package 1000d and the logic chip 700 to the package substrate 100.

For example, the interposer substrate 601 may be formed of any one of silicon, an organic material, plastic, and a glass substrate. However, the material of the interposer substrate 601 is not limited to the above materials. When the interposer substrate 601 is a silicon substrate, the interposer 600 may be referred to as a silicon interposer. In addition, when the interposer substrate 601 is an organic material substrate, the interposer 600 may be referred to as a panel interposer.

The upper protective layer 603 may be arranged on the upper surface of the interposer substrate 601, and the upper pad 605 may be arranged on the upper protective layer 603. The upper pad 605 may be connected to the through electrode 630. The semiconductor package 1000d and the logic chip 700 may be stacked on the interposer 600 through bumps 320c arranged on the upper pad 605. The line layer 610 may be arranged on the lower surface of the interposer substrate 601 and have a single-layered structure or a multi-layered structure.

The through electrode 630 may penetrate the interposer substrate 601 and extend. In addition, the through electrode 630 may extend to the inside of the line layer 610 to be electrically connected to lines of the line layer 610. When the interposer substrate 601 includes silicon, the through electrode 630 may be referred to as a TSV. According to embodiments, the interposer 600 may also include only a line layer therein, and a through electrode may be not included.

In the semiconductor device 10000 of the embodiment, the interposer 600 may be used to convert or transmit signals between the semiconductor package 1000d and the logic chip 700, between the package substrate 100 and the semiconductor package 1000d, or between the package substrate 100 and the logic chip 700. Accordingly, the interposer 600 may not include elements such as active elements or passive elements. In the interposer 600, although the line layer 610 is arranged on the lower portion of the through electrode 630, but according to embodiments, the line layer 610 may also be arranged on the upper portion of the through electrode 630. For example, the positional relationship between the line layer 610 and the through electrode 630 may be relative.

The bump 620 may be arranged on the lower surface of the interposer 600 and may be electrically connected to a line of the line layer 610. The interposer 600 may be mounted on the package substrate 100 through the bump 620. The bump 620 may be connected to the upper pad 605 through the lines of the line layer 610 and the through electrode 630.

The logic chip 700 may be a processor chip. For example, the logic chip 700 may be a GPU/CPU/SOC chip. Depending on the type of elements included in the logic chip 700, the semiconductor device 10000 may be distinguished into a server-type semiconductor device or a mobile-type semiconductor device, or the like.

Although not illustrated in the drawing, the semiconductor device 10000 may include an internal sealant that seals the semiconductor package 1000d and the logic chip 700 on the interposer 600. In addition, the semiconductor device 10000 may include an external sealant that seals the interposer 600 and the internal sealant on the package substrate 100. According to embodiments, the external sealant and the internal sealant may not be distinguished by being formed together. In addition, according to embodiments, the internal sealant may cover only the upper surface of the logic chip 700 but may not cover the upper surface of the semiconductor package 1000d.

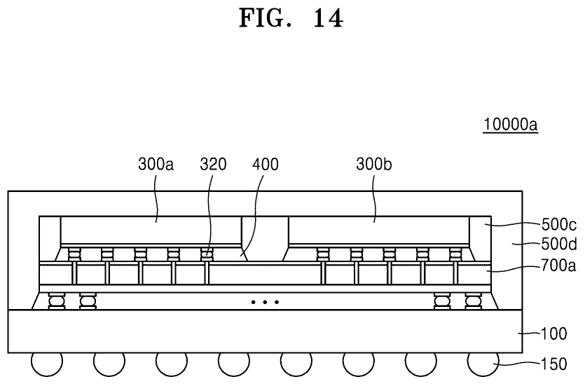

For example, the structure of the semiconductor device 10000 as in the embodiment is referred to as a 2.5 dimensional (D) package structure, and the 2.5D package structure may be a relative concept to a 3D package structure without an interposer. Both the 2.5D package structure and the 3D package structure may be included in a system-in-package (SIP) structure. The semiconductor device 10000 of the embodiment may also be a type of semiconductor package. However, because the semiconductor device 10000 may include the semiconductor package 1000d corresponding to the semiconductor packages 1000 and 1000a to 1000b of FIGS. 11A to 12, it is called a semiconductor device to be terminologically distinguished from the semiconductor package 1000d. Hereinafter, the same concept may also be applied to the semiconductor device 10000a of FIG. 14.

FIG. 14 is a cross-sectional view of a semiconductor device according to an embodiment. Description is made with reference to FIGS. 1A and 1B together, and descriptions already given with reference to FIGS. 1A to 12 are briefly given or omitted.

Referring to FIG. 14, the semiconductor device 10000a of the embodiment may include the package substrate 100, the external connection terminal 150, first and second memory chips 300a and 300b, a logic chip 700a, an internal sealant 500c, and an external sealant 500d. The package substrate 100 may be the package substrate 100 of FIG. 1A or the package substrate 100a of FIG. 9. The external connection terminal 150 may be arranged on the lower surface of the package substrate 100.

Two memory chips including the first and second memory chips 300a and 300b may be mounted on the logic chip 700a. The two memory chips including the first and second memory chips 300a and 300b may also be the same memory chips. For example, the two memory chips including the first and second memory chips 300a and 300b may all be SRAM chips. However, according to embodiments, the two memory chips including the first and second memory chips 300a and 300b may be different memory chips. For example, the first memory chip 300a may be an SRAM chip, and the second memory chip 300b may be a DRAM chip.

The number of memory chips stacked on the logic chip 700a is not limited to two. For example, one or three or more memory chips may be stacked on the logic chip 700a. In addition, the type of memory chips is not limited to an SRAM chip or a DRAM chip. For example, various types of memory chips described above may be included in the semiconductor device 10000a of the embodiment. Furthermore, a memory package may also be mounted on the logic chip 700a instead of the two memory chips including the first and second memory chips 300a and 300b. The memory package may include at least two memory chips. In addition, three or more memory packages may also be mounted on the logic chip 700a.

The logic chip 700a may be mounted on the package substrate 100. The logic chip 700a may include various types of processor chips, such as GPU/CPU/SOC chips or the like. The internal sealant 500c may seal the first and second memory chips 300a and 300b on the logic chip 700a. In addition, the external sealant 500d may seal the logic chip 700a on the package substrate 100 and the internal sealant 500c. Because the logic chip 700a is stacked on the package substrate 100, and the first and second memory chips 300a and 300b are stacked on the logic chip 700a, the semiconductor device 10000a of the embodiment may correspond to a 3D package structure.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

The invention claimed is:

1. A package substrate comprising:
a core layer;
a first line layer on a lower surface of the core layer and including multiple layers of first lines; and
a second line layer on an upper surface of the core layer and including multiple layers of second lines, wherein
the core layer includes a core body and a core via,
the core via penetrates the core body and extends in a vertical direction,
a first signal line of the first lines is connected to a second signal line of the second lines through the core via, and
the first signal line is arranged in a form of an inductor in the first line layer.

2. The package substrate of claim 1, wherein the first signal line has a spring form extending in the vertical direction while rotating clockwise or counterclockwise in the first line layer.

3. The package substrate of claim 2, wherein
the spring form has a circular form, an oval form, or a polygonal form when viewed on a plane perpendicular to the vertical direction.

4. The package substrate of claim 1, wherein
the first signal line comprises a horizontal line, a vertical via, and adjacent horizontal lines in the vertical direction,
the horizontal line extends on a plane perpendicular to the vertical direction, and
the vertical via connects the adjacent horizontal lines in the vertical direction to each other.

5. The package substrate of claim 4, wherein the horizontal line configures the inductor to have a structure that rotates clockwise or counterclockwise while the horizontal line is connected to one of the adjacent horizontal lines in the vertical direction through the vertical via.

6. The package substrate of claim 4, wherein
the vertical via is part of a first vertical via group arranged at a first position on the plane or a second vertical via group arranged at a second position spaced apart from the first position on the plane,
the horizontal line is part of a first horizontal line group at a first side of the inductor or a second horizontal line group at a second side of the inductor.

7. (canceled)

8. (canceled)

9. The package substrate of claim 1, further comprising:
a lower substrate pad on a lower surface of the package substrate; and
an external connection terminal on a lower surface of the lower substrate pad, wherein
a portion of the lower substrate pad overlaps a ground line or a power line of the first lines in the vertical direction.

10. The package substrate of claim 1, further comprising:
a lower substrate pad on a lower surface of the package substrate; and
an external connection terminal on a lower surface of the lower substrate pad, wherein
the core layer includes a core pad overlapping the first line layer, and
a dielectric void filled only with a dielectric material is not formed between the lower substrate pad and the first line layer overlapping a core pad of the core via.

11. A package substrate comprising:
a body layer having an upper surface and a lower surface; and
multiple layers of lines in the body layer, wherein
the lines comprise a signal line configured to transmit a signal,
the signal line comprises a horizontal line and a vertical via,
the horizontal line extends in the body layer in a horizontal direction parallel to the upper surface of the body layer,
the vertical via is configured to connect adjacent horizontal lines in a vertical direction to each other in the body layer, the vertical direction is perpendicular to the horizontal direction, and
the horizontal line and the vertical via configure an inductor in the body layer.

12. The package substrate of claim 11, wherein
the body layer comprises a core body at a center of the body layer in the vertical direction, a first body on a lower portion of the core body, and a second body on an upper portion of the core body,
the lines comprise first lines in the first body and second lines in the second body,
the signal line comprises a first signal line among the first lines and a second signal line among the second lines, and
the first signal line is connected to the second signal line through a core via penetrating the core body and forms the inductor in the first body.

13. The package substrate of claim 12, wherein the first signal line has a spring form extending in the vertical direction while rotating clockwise or counterclockwise in the first body.

14. The package substrate of claim 13, wherein
the first signal line comprises a first horizontal line among horizontal lines in the first body and a first vertical via among vertical vias in the first body,
the first vertical via connects adjacent first horizontal lines in the vertical direction to each other, and
the first horizontal line configures the inductor to have a structure that rotates clockwise or counterclockwise while being connected to a first horizontal line of an other layer through the first vertical via.

15. The package substrate of claim 12, further comprising:
a lower substrate pad is on a lower surface of the body layer; and
an external connection terminal on a lower surface of the lower substrate pad, wherein
a portion of the lower substrate pad overlaps a ground line or a power line of the first lines in the vertical direction.

16. The package substrate of claim 11, wherein
the horizontal line comprises a first horizontal line in the body layer as a part of the inductor and a second horizontal line at an uppermost portion of the body layer, and
the vertical via is configured to connect adjacent first horizontal lines in the vertical direction to each other, connect the first horizontal line at an uppermost portion to the second horizontal line, or connect the first horizontal line at a lowermost portion to a lower substrate pad on the lower surface of the body layer.

17. The package substrate of claim 16, wherein the first horizontal line configures the inductor to have a structure that rotates clockwise or counterclockwise while being connected to an other first horizontal line of an other layer through the vertical via.

18. A semiconductor package comprising:
a package substrate;
at least one semiconductor device mounted on the package substrate; and
a sealant configured to seal the at least one semiconductor device on the package substrate,
wherein the package substrate comprises
a body layer having an upper surface and a lower surface and multiple layers of lines in the body layer,
the lines comprise a signal line configured to transmit a signal,
the signal line comprises a horizontal line and a vertical via, the horizontal line extending in the body layer in a horizontal direction parallel to the upper surface of the body layer, and the vertical via being configured to connect adjacent horizontal lines in a vertical direction to each other in the body layer, and
the horizontal line and the vertical via configure an inductor in the body layer.

19. The semiconductor package of claim 18, wherein
the body layer comprises a core body at a center of the body layer in the vertical direction, a first body on a lower portion of the core body, and a second body on an upper portion of the core body,
the lines comprise first lines in the first body and second lines in the second body,
the signal line comprises a first signal line among the first lines and a second signal line among the second lines, and
the first signal line is connected to the second signal line through a core via penetrating the core body and forms the inductor in the first body.

20. The semiconductor package of claim 19, wherein the first signal line has a spring form extending in the vertical direction while rotating clockwise or counterclockwise in the first body.

21. The semiconductor package of claim 19, wherein
the package substrate further includes a lower substrate pad on the lower surface of the body layer and an external connection terminal on a lower surface of the lower substrate pad, and
a portion of the lower substrate pad overlaps a ground line or a power line of the first lines in the vertical direction.

22. The semiconductor package of claim 18, wherein
the horizontal line comprises a first horizontal line in the body layer as a part of the inductor and a second horizontal line at an uppermost portion of the body layer, and
the vertical via is configured to connect adjacent first horizontal lines in the vertical direction to each other, connect the first horizontal line at an uppermost portion to the second horizontal line, or connect the first horizontal line at a lowermost portion to a lower substrate pad arranged on the lower surface of the body layer.

23.-25. (canceled)
